(19) United States
(12) Patent Application Publication
(10) Pub. No.: US 2025/0258202 A1
(43) Pub. Date: Aug. 14, 2025

(54) CORRECTED CURRENT MEASUREMENTS USING MULTIPLE MAGNETIC FIELD SENSORS

(71) Applicant: Tektronix, Inc., Beaverton, OR (US)

(72) Inventors: Mark A. Norris, Louisville, CO (US); Daniel G. Knierim, Beaverton, OR (US)

(21) Appl. No.: 19/005,822

(22) Filed: Dec. 30, 2024

Related U.S. Application Data
(60) Provisional application No. 63/553,112, filed on Feb. 13, 2024.

(51) Int. Cl. G01R 15/20; G01R 19/25

(52) U.S. Cl. CPC G01R 15/207; G01R 19/2506

(57) ABSTRACT

A current measurement probe includes two or more magnetic field sensors having a known geometric relationship to allow conversion of signals from the field sensors to a current measurement using the relationship. A test and measurement system includes a current measurement probe including two or more magnetic field sensors having a known geometric relationship to allow conversion of signals from the magnetic field sensors to a current measurement, a test and measurement instrument having at least one port to connect to the current measurement probe, and circuitry to receive the signals from the magnetic field sensors and convert the signals to the current measurement. A method for measuring current includes applying a current measurement probe to a substrate having a conductor carrying current, the current measurement probe having at least two magnetic field sensors having a known geometric relationship, converting signals from the magnetic field sensors to a current measurement.

### RELATED APPLICATIONS

This disclosure is a non-provisional of and claims benefit from U.S. Provisional Application No. 63/553,112, titled “CORRECTED CURRENT MEASUREMENTS USING MULTIPLE MAGNETIC FIELD SENSORS” filed on Feb. 13, 2024, the disclosure of which is incorporated herein by reference in its entirety.

### TECHNICAL FIELD

This disclosure relates to test and measurement instruments, and more particularly to devices and methods for measuring electrical current.

### BACKGROUND

Many current measurement techniques require surrounding the current carrying conductor to measure all the magnetic flux given off by the current flowing through the conductor. Additionally, the added inductance of some wrap-around current probes distorts the operation of the circuit under test, slowing or adding ringing, etc. Measuring current by resulting magnetic fields and magnetic field sensor probes meant to read current flow are available on the market today. Generally, these probes are not calibrated and sensitive to the exact placement of the probe relative to the wire or trace. U.S. Pat. No. 11,619,697, “CALIBRATION OF MAGNETIC FIELD SENSORS FOR CURRENT PROBE,” issued Apr. 4, 2023, describes a method of calibrating probes, incorporated by reference herein in its entirety.

Additionally, wrapping a current probe fully around the conductor is physically impossible for many applications. Improving magnetic field sensors that do not require calibrations or wrapping around the conductor would comprise a significant improvement.

### BRIEF DESCRIPTION OF THE DRAWINGS

FIG. 1 shows a field diagram around a conductor with two points for sensing.

FIG. 2 shows a field diagram around a conductor in a substrate structure with multiple points for sensing.

FIG. 3 shows a block diagram of the relationships between current in a trace, the trace, a ground plane, and a probe.

FIG. 4 shows an initial and resulting measured magnetic fields of a trace above a ground plane with three sensors.

FIG. 5 shows an initial and resulting measured magnetic fields of a trace above a ground plane with four sensors.

FIG. 6 shows an embodiment of a magnetic probe having multiple magnetic sensors at known distances from each other attached to a test and measurement instrument.

### DESCRIPTION

A probe that does not need to wrap around a current carrying conductor represents a significant improvement for some current measurement applications. However, the measurement of a single magnetic field point to avoid wrapping the conductor depends on the geometry of conductor, the location of the measurement point, the external fields as well as the current through the conductor.

Embodiments herein include a probe with multiple single point magnetic field sensors. The additional measurement points enable correction for geometry of the current carrying conductor, the location of the probe to the conductor and external fields, etc. The probe can measure the current in the conductor without having to know the distance between the conductor and the magnetic field sensors.

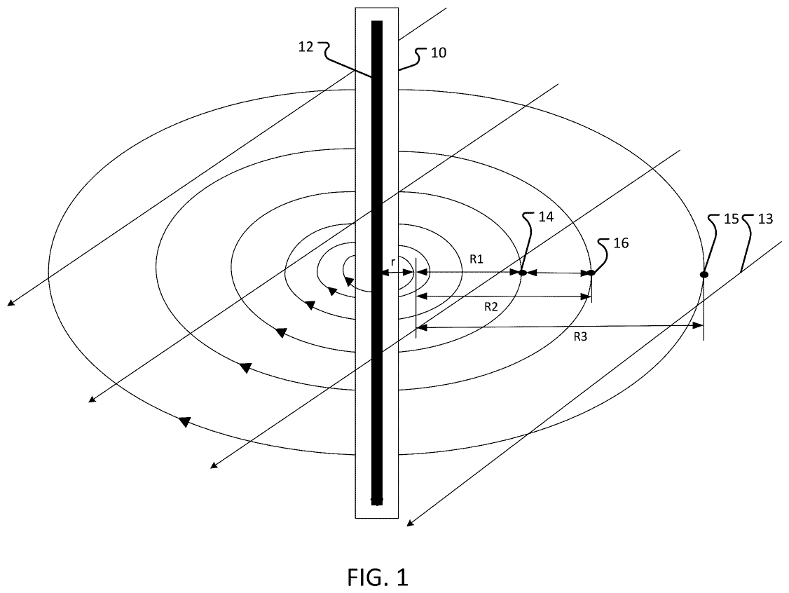

FIG. 1 illustrates taking two magnetic field measurements at distances r+R₁ and r+R₂ from the conductor 10 carrying current 12. The distances between the center conductor 10 and the sensor positions 14, 16, and 15 are not known. The known spacing between the two or three sensors allows for the simultaneous calculation of the current through the conductor. The discussion of the embodiments includes two of the two or more magnetic field sensors that are positioned on the same line and positionable perpendicular to the current path when the measurements are made. However, many other configurations are possible, and no limitation exists to any particular geometric relationship between the magnetic field sensors. The magnetic field sensors have a known geometric relationship. The known geometric relationship allows for the calculation of current in the conductor.

In the below formulas, the sensors positions 14, 16, and 15, are occupied by the sensors, that measure the field strength as measures S₁, S₂, and S₃, The sensor at position 15 having a distance R₃ from the center conductor detects a field strength S₃, which is used to cancel an external field shown by field lines such as 13. The formulas for calculating the magnetic field strength at point 14, which is the location of the first sensor the detects field strength S₁, and 16, which detects the field strength S₂ are:

$$\begin{matrix}{S}_{1} = \frac{{Iu}_{0}}{r + {R}_{1}} , \\ {S}_{2} = \frac{{Iu}_{0}}{r + {R}_{2}} .\end{matrix}$$

By solving the two equations simultaneously, one can eliminate the unknown r, and solve for the unknown current, I,

$$I = \frac{{S}_{1} {S}_{S} ( - {R}_{1} + {R}_{2} )}{{u}_{0} ( {S}_{1} - {S}_{2} )} ,$$

where u₀ is the relative permittivity of free space, a scaling parameter that relates current flow to magnetic field.

The number of magnetic field sensors may be two, three, or more. As an example, the calculations for the third point would be:

$$\begin{matrix}{S}_{1} = \frac{{Iu}_{0}}{{R}_{1} + r} + e x t \\ {S}_{2} = \frac{{Iu}_{0}}{{R}_{2} + r} + e x t \\ {S}_{3} = \frac{{Iu}_{0}}{{R}_{3} + r} + e x t ,\end{matrix}$$

where ext is the external magnetic field.
Solving for current, one can use the magnetic field measurements to determine current:

$$I = \frac{( {R}_{1} - {R}_{2} ) ( {R}_{1} - {R}_{3} ) ( {R}_{2} - {R}_{3} ) ( {S}_{1} - {S}_{2} ) ( {S}_{1} - {S}_{3} ) ( {S}_{2} - {S}_{3} )}{- {{u}_{0} ( {R}_{1} {S}_{2} - {R}_{1} {S}_{3} - {R}_{2} {S}_{1} + {R}_{2} {S}_{3} + {R}_{3} {S}_{1} - {R}_{3} {S}_{2} )}^{2}} .$$

The above calculations assume that there is no ground plane that would affect the magnetic field signals from the sensors.

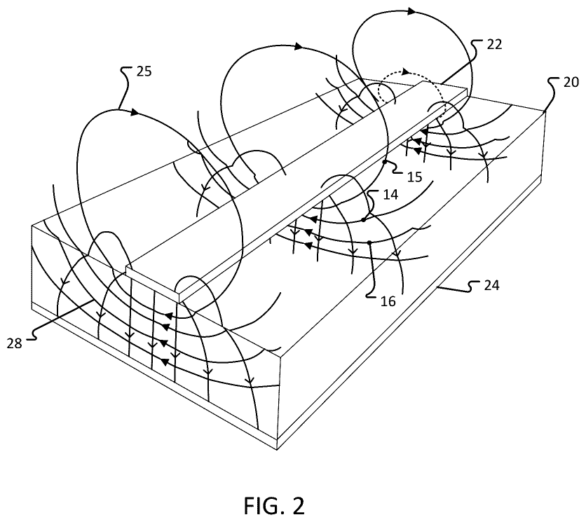

In the embodiment of FIG. 2, substrate 20 has a ground plane 24. The ground plane 24 separated from current carrying trace 22 by substrate 20 distorts the magnetic field 25 from the circular shape of the field around a wire in free space of FIG. 1 as shown by magnetic flux 28. The return current in the ground plane 24 exactly cancels the magnetic flux, 28, of the current carrying trace 22.

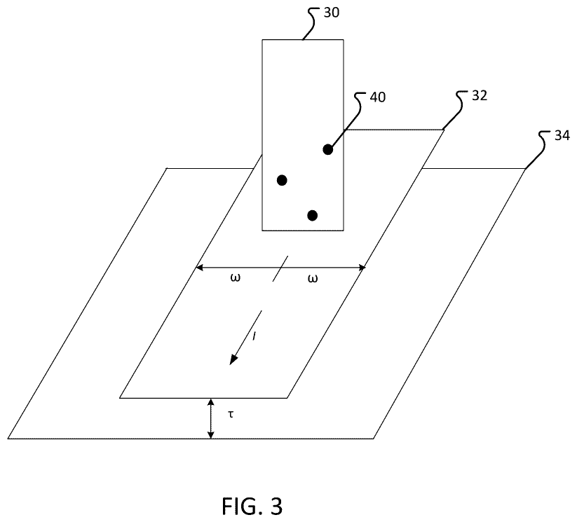

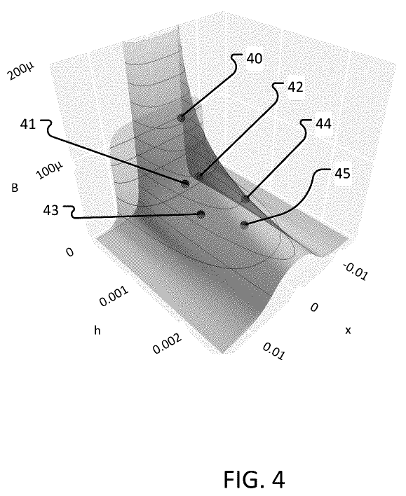

FIG. 3 shows a block diagram of the relationship between the current, I, in trace 32, the width, 2*ω, of the trace, and the distance to the ground plane 34, τ. Probe 30, having three sensors such as 40, is held perpendicular to the trace 32. FIG. 4 shows a magnetic field, B, sensed by sensors at three points 40, 42, and 44. The field has the three unknown parameters, I, ω, τ, above the ground plane. The probe is perpendicular to the center of the trace and has the three known x positions relative to the center of the trace and height h above the trace, because the relative position of each sensor is known. The sensors measure the B field at each sensor site. The sensors have positions [(x1, h1), (x2, h2), (x3, h3)], and provide field measurements, [B1, B2, B3]. This leads to the analytic solution for the B field of a current carrying trace above a ground plane:

$$B ( x , h ) = \frac{I \cdot {μ}_{0}}{4 π \cdot w} ( asinh ( \frac{ω - x}{\vert h \vert} ) + a sinh ( \frac{ω + x}{\vert h \vert} ) - a sinh ( \frac{ω - x}{\vert 2 τ + h \vert} ) - a sinh ( \frac{ω + x}{\vert 2 τ + h \vert} ) ) .$$

The terms with denominator |2τ+h| are the mirrored virtual currents. The embodiments here only need to determine the B field at each sensor point above.

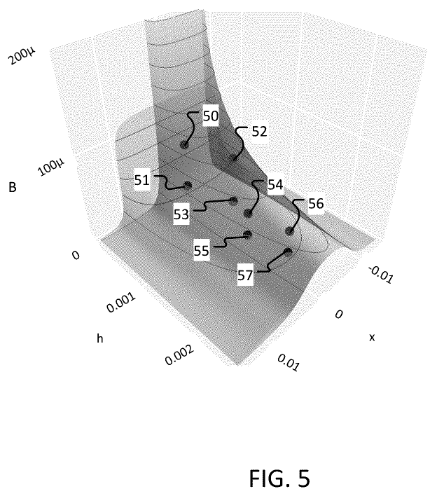

One or more processors may execute code configured to cause the one or more processors to act as a numeric optimizer to perform numeric optimization by varying I, ω, and τ, in the above equation. This will continue until the optimization finds a match to the B field measured at each point. In FIG. 3, the sensor locations 40, 42, and 44 have measured the field, and the optimization process estimates an initial field at 41, 43, and 45. The process iterates until the match is found. This then gives the user the current, I, the width of the trace from ω, and the trace height above the ground plane, τ. In an example, an initial starting point for the field is I=1.0, ω=0.01, and τ=0.002. Using the optimization, the final field that matches the field measured at each point is I=2.0, ω=0.005, and τ=0.001. In the final matched configuration, the B field at each sensor point 40, 42 and 44 computed by the field solution match the measured field at each sensor point. FIG. 5 shows an embodiment with four sensors, 50, 52, 54, and 56, with the initial field represented 51, 53, 55, and 57.

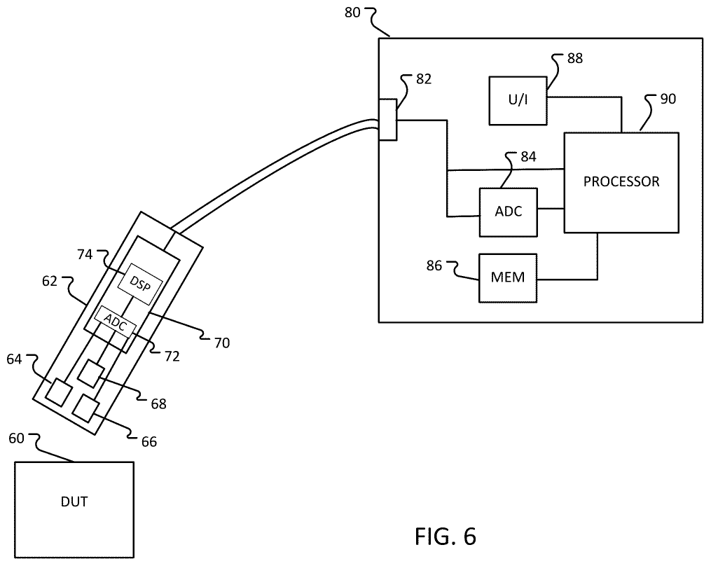

FIG. 6 shows an embodiment of the current sensor probe attached to a test and measurement instrument. Probe 62 has two or more magnetic field sensors such as 64, 66, and 68, having a known geometric relationship. A user employs probe 62 to test the magnetic field generated by a current flowing in a conductor on the DUT 60, such as the conductors shown in FIGS. 1 and 2. Probe 62 sends information to the test and measurement instrument 80. The information sent from the probe to the test and measurement instrument may take many forms depending upon the presence and nature of any circuitry 70 on the probe.

The on-probe circuitry 70 may comprise one of several embodiments or combinations thereof. In one embodiment, the circuitry comprises analog circuitry to convert the signals from the magnetic field sensors to a current measurement. In this embodiment the information sent to the test and measurement instrument comprises an analog signal.

The circuitry 70 may comprise digital circuitry. In one embodiment, one or more analog-to-digital converters (ADC), such as 72 digitize the signals from the magnetic field sensors. In one embodiment, the ADC converts the signals to digital data and the information transmitted to the test and measurement instrument 80 comprises digitized signals from the magnetic field sensors for the test and measurement instrument to convert to the current measurement. Magnetic field sensors may also send their signals in digital form, which would not require conversion.

In another embodiment, the circuitry 70 may comprise one or more processors, such as 74. As used herein, the term “processor” means any device that can execute code to perform the necessary conversion from magnetic field sensor signals to current measurements. This may include digital signals processors (DSP), general-purpose processors, and field programmable gate arrays (FPGA), as examples. In this embodiment, one or more processors receive the digitized signals resulting from the ADC converting the signals from the magnetic field sensors, or digital signals from the sensors directly. The one or more processors then execute code to produce the current measurement. The one or more processors then transmit the current measurement to the test and measurement instrument.

As mentioned above, any circuitry to perform the conversion on the probe is optional. The test and measurement may receive the raw signals from the probe in either analog or digital form and perform the conversion from magnetic field signals to current measurement.

The test and measurement instrument 80 has port(s) 82 to allow probe 62 to connect to the test and measurement instrument. If the signals from the probe comprise analog signals from the magnetic field sensors, the ADC 84 may convert them to digital signals and the one or more processors 90 would convert the digital signals to the current measurement. If the signals received comprise digital signals, either unconverted digital signals from the sensors, or the current measurement, the signals would bypass ADC 84. The test and measurement instrument 80 may include a memory 86 to allow the one or more processors to store the current measurement, and/or the incoming signals, and may contain the code to be executed by the one or more processors. User interface 88 allows the test and measurement instrument to display at least the resulting current measurement to the user, and may include controls to allow the user to perform operations on the incoming signals, etc.

As discussed above, one method of determining the current measurement comprises solving simultaneous equations to determine the current from the field strengths at locations having a known geometric relationship between the sensors. This comprises one form of generating a magnetic field solution. The term “magnetic field solution” as used here provides the strength of the magnetic field that allows conversion to current. Other options for determining a magnetic field solution exist. In one embodiment, a magnetic field solver may use the signals from the magnetic field sensors to determine the magnetic field solution. As used here, the term “magnetic field solver” involves code that causes the one or more processors to employ Maxwell's equations to determine the magnetic field solution.

In another embodiment, one or more processors may use the information from the magnetic field sensors as an index, or indices, into a lookup table to determine the magnetic field solution. The lookup table may reside in the memory of the test and measurement instrument.

The ability to determine a magnetic field solution in this manner allows for measurement of other parameters, as discussed above with regard to FIG. 4. The magnetic field solution can match the signals from the magnetic field sensors to determine values of one or more parameters, such as the current, width of the trace carrying the current, and the height of the trace above a ground plane. Other applications include non-invasively sensing the signals flowing through conductors in communications systems. Another additional application allows safely measuring the current through a conductor from a distance.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

### EXAMPLES

Illustrative examples of the disclosed technologies are provided below. An embodiment of the technologies may include one or more, and any combination of, the examples described below.

Example 1 is a current measurement probe comprising two or more magnetic field sensors having a known geometric relationship to each other to allow conversion of signals from the two or more magnetic field sensors to a current measurement using the known geometric relationship.

Example 2 is the current measurement probe of Example 1, wherein the known geometric relationship comprises at least two of the two or more magnetic field sensors positioned in a same line perpendicular to a current path to be measured and on a same side of the current path.

Example 3 is the current measurement probe of either Example 1 or Example 2, further comprising circuitry to receive the signals from the two or more magnetic field sensors and to convert the signals to the current measurement.

Example 4 is the current measurement probe of Example 3, wherein the circuitry to convert the signals to the current measurement comprises analog circuitry.

Example 5 is the current measurement probe of Example 3, wherein the circuitry to convert the signals to the current measurement comprises digital circuitry.

Example 6 is the current measurement probe of Example 3, wherein the circuitry to convert the signals to the current measurement comprises: one or more analog-to-digital converters (ADC) to receive the signals and convert the signals to digital signals; and one or more processors configured to execute code to cause the one or more processors to convert the digital signals to a current measurement.

Example 7 is the current measurement probe of any of Examples 1 through 6, wherein the two or more magnetic field sensors comprise three or more magnetic field sensors.

Example 8 is a test and measurement system, comprising: a current measurement probe comprising two or more magnetic field sensors having a known geometric relationship to each other to allow conversion of signals from the two or more magnetic field sensors to a current measurement using the known geometric relationship, a test and measurement instrument having at least one port to allow the test and measurement instrument to connect to the current measurement probe, and circuitry to receive the signals from the two or more magnetic field sensors and to convert the signals to the current measurement.

Example 9 is the test and measurement system of Example 8, wherein the circuitry resides in one of either the current measurement probe or the test and measurement instrument.

Example 10 is the test and measurement system of either Example 8 or Example 9, wherein the circuitry to convert the signals comprises analog circuitry.

Example 11 is the test and measurement system of any of Examples 8 through 10, wherein the circuitry to convert the signals comprises digital circuitry.

Example 12 is the test and measurement system any of Examples 8 through 11, wherein the circuitry to receive the signals from the two or more magnetic field sensors and to convert the signals to the current measurement comprises: one or more analog-to-digital converters (ADC) to receive the signals and convert the signals to digital signals, and one or more processors configured to execute code that causes the one or more processors to convert the digital signals to the current measurement.

Example 13 is the test and measurement system of any of Examples 8 through 12, wherein the two or more magnetic field sensors comprise three or more magnetic field sensors.

Example 14 is a method for measuring current, comprising: applying a current measurement probe to a substrate having a conductor carrying current, the current measurement probe having at least two magnetic field sensors having a known geometric relationship; and converting signals from the two or more magnetic field sensors to a current measurement.

Example 15 is the method of Example 14, wherein converting the signals comprises converting the signals using analog circuitry.

Example 16 is the method of either Example 14 or Example 15, wherein converting the signals comprises: using one or more analog-to-digital converters (ADC) to convert the signals to digital signals; and performing digital signal processing to convert the digital signals to the current measurement.

Example 17 is the method of any of Examples 14 through 16, wherein applying the current measurement probe comprises applying the current measurement probe without having to wrap the current measurement probe around the conductor.

Example 18 is the method of any of Examples 14 through 17, wherein converting the signals comprises generating a magnetic field solution by using the known geometric relationship to do one of solving two or more simultaneous equations, using a field solver, or using a lookup table.

Example 19 is the method of any of Examples 14 through 18, wherein applying the current measurement probe comprises applying a current measurement probe having three or more sensors.

Example 20 is the method of Example 19, wherein converting the signals comprises using the signals from the field sensors in a numeric optimizer to calculate one or more of current being carried in a trace, a width of the trace, and a height of the trace above the ground plane.

Example 21 is the method of any of Examples 14 through 120, wherein applying the current measurement probe comprises applying a current measurement probe having four or more sensors.

Example 22 is the method of Example 21, wherein converting the signals comprises using the signals from the field sensors in a numeric optimizer to calculate one or more of a current being carried in a trace, a width of the trace, a height of the trace above the ground plane, a position of one or more sensors relative to a center of the trace, and an external field.

Additionally, this written description makes reference to particular features. It is to be understood that the disclosure in this specification includes all possible combinations of those particular features. For example, where a particular feature is disclosed in the context of a particular aspect, that feature can also be used, to the extent possible, in the context of other aspects.

Also, when reference is made in this application to a method having two or more defined steps or operations, the defined steps or operations can be carried out in any order or simultaneously, unless the context excludes those possibilities.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Although specific aspects of this disclosure have been illustrated and described for purposes of illustration, it will be understood that various modifications may be made without departing from the spirit and scope of the invention. Accordingly, the invention should not be limited except as by the appended claims.

1. A current measurement probe comprising two or more magnetic field sensors having a known geometric relationship to each other to allow conversion of signals from the two or more magnetic field sensors to a current measurement using the known geometric relationship.

2. The current measurement probe as claimed in claim 1, wherein the known geometric relationship comprises at least two of the two or more magnetic field sensors positioned in a same line perpendicular to a current path to be measured and on a same side of the current path.

3. The current measurement probe as claimed in claim 1, further comprising circuitry to receive the signals from the two or more magnetic field sensors and to convert the signals to the current measurement.

4. The current measurement probe as claimed in claim 3, wherein the circuitry to convert the signals to the current measurement comprises analog circuitry.

5. The current measurement probe as claimed in claim 3, wherein the circuitry to convert the signals to the current measurement comprises digital circuitry.

6. The current measurement probe as claimed in claim 3, wherein the circuitry to convert the signals to the current measurement comprises:
one or more analog-to-digital converters (ADC) to receive the signals and convert the signals to digital signals; and
one or more processors configured to execute code to cause the one or more processors to convert the digital signals to a current measurement.

7. The current measurement probe as claimed in claim 1, wherein the two or more magnetic field sensors comprise three or more magnetic field sensors.

8. A test and measurement system, comprising:
a current measurement probe comprising two or more magnetic field sensors having a known geometric relationship to each other to allow conversion of signals from the two or more magnetic field sensors to a current measurement using the known geometric relationship;
a test and measurement instrument having at least one port to allow the test and measurement instrument to connect to the current measurement probe; and
circuitry to receive the signals from the two or more magnetic field sensors and to convert the signals to the current measurement.

9. The test and measurement system as claimed in claim 8, wherein the circuitry resides in one of either the current measurement probe or the test and measurement instrument.

10. The test and measurement system as claimed in claim 8, wherein the circuitry to convert the signals comprises analog circuitry.

11. The test and measurement system as claimed in claim 8, wherein the circuitry to convert the signals comprises digital circuitry.

12. The test and measurement system as claimed in 8, wherein the circuitry to receive the signals from the two or more magnetic field sensors and to convert the signals to the current measurement comprises:
one or more analog-to-digital converters (ADC) to receive the signals and convert the signals to digital signals; and
one or more processors configured to execute code that causes the one or more processors to convert the digital signals to the current measurement.

13. The test and measurement system as claimed in claim 8, wherein the two or more magnetic field sensors comprise three or more magnetic field sensors.

14. A method for measuring current, comprising:
applying a current measurement probe to a substrate having a conductor carrying current, the current measurement probe having at least two magnetic field sensors having a known geometric relationship; and
converting signals from the two or more magnetic field sensors to a current measurement.

15. The method as claimed in claim 14, wherein converting the signals comprises converting the signals using analog circuitry.

16. The method as claimed in claim 14, wherein converting the signals comprises:
using one or more analog-to-digital converters (ADC) to convert the signals to digital signals; and
performing digital signal processing to convert the digital signals to the current measurement.

17. The method as claimed in claim 14, wherein applying the current measurement probe comprises applying the current measurement probe without having to wrap the current measurement probe around the conductor.

18. The method as claimed in claim 14, wherein converting the signals comprises generating a magnetic field solution by using the known geometric relationship to do one of solving two or more simultaneous equations, using a field solver, or using a lookup table.

19. The method as claimed in claim 14, wherein applying the current measurement probe comprises applying a current measurement probe having three or more sensors.

20. The method as claimed in claim 19, wherein converting the signals comprises using the signals from the field sensors in a numeric optimizer to calculate one or more of current being carried in a trace, a width of the trace, and a height of the trace above the ground plane.

21. The method as claimed in claim 14, wherein applying the current measurement probe comprises applying a current measurement probe having four or more sensors.

22. The method as claimed in claim 21, wherein converting the signals comprises using the signals from the field sensors in a numeric optimizer to calculate one or more of a current being carried in a trace, a width of the trace, a height of the trace above the ground plane, a position of one or more sensors relative to a center of the trace, and an external field.
